(19) United States
(12) Patent Application Publication
(10) Pub. No.: US 2025/0169167 A1
(43) Pub. Date: May 22, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Shao-Jyun WU, New Taipei (TW); Yung Feng CHANG, Hsinchu (TW)

(21) Appl. No.: 18/512,320

(22) Filed: Nov. 17, 2023

(51) Int. Cl. H01L 27/088; H01L 29/06; H01L 29/40; H01L 29/423; H01L 29/45; H01L 29/66; H01L 29/775; H01L 29/786

(52) U.S. Cl. CPC H10D 84/83; H10D 30/43; H10D 30/6735; H10D 30/6757; H10D 62/121; H10D 62/83; H10D 64/01; H10D 64/017; H10D 64/62

(57) ABSTRACT

Embodiments of the present disclosure provide semiconductor device structures and methods of forming the same. The structure includes a first source/drain region, a second source/drain region disposed adjacent the first source/drain region along a first direction, a third source drain region, a fourth source/drain region disposed adjacent the third source/drain region along the first direction, a first dielectric layer having a first end and a second end opposite the first end, a conductive contact disposed between the first and third source/drain regions and between the second and fourth source/drain regions, and the conductive contact is disposed in the first dielectric layer. The structure further includes a conductive feature disposed in the first dielectric layer, and the conductive feature is electrically connected to the conductive contact.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of various stages of manufacturing a semiconductor device structure, in accordance with some embodiments.

FIGS. 7A-10A are cross-sectional side views of various stages of manufacturing the semiconductor device structure taken along line A-A of FIG. 6, in accordance with some embodiments.

FIGS. 7B-10B are cross-sectional side views of various stages of manufacturing the semiconductor device structure taken along line B-B of FIG. 6, in accordance with some embodiments.

FIGS. 7C-10C are cross-sectional side views of various stages of manufacturing the semiconductor device structure taken along line C-C of FIG. 6, in accordance with some embodiments.

FIG. 11 is a top view of the semiconductor device structure shown in FIGS. 10A, 10B, 10C, in accordance with some embodiments.

FIGS. 12A-18A are cross-sectional side views of various stages of manufacturing the semiconductor device structure taken along line D-D of FIG. 11, in accordance with some embodiments.

FIGS. 12B-18B are cross-sectional side views of various stages of manufacturing the semiconductor device structure taken along line E-E of FIG. 11, in accordance with some embodiments.

FIG. 19 is a top view of the semiconductor device structure shown in FIGS. 18A and 18B, in accordance with some embodiments.

FIGS. 20A, 20B, 20C are various views of one of various stages of manufacturing the semiconductor device structure, in accordance with some embodiments.

FIGS. 21A, 21B, 21C, 21D are various views of one of various stages of manufacturing the semiconductor device structure, in accordance with some embodiments.

FIGS. 22A, 22B, 22C, 22D are various views of one of various stages of manufacturing the semiconductor device structure, in accordance with some embodiments.

FIGS. 23A, 23B, 23C are cross-sectional side views of one of various stages of manufacturing the semiconductor device structure, in accordance with some embodiments.

FIGS. 24A-26A are cross-sectional side views of various stages of manufacturing the semiconductor device structure taken along line F-F of FIG. 21A, after the semiconductor device structure is flipped over, in accordance with some embodiments.

FIGS. 24B-26B are cross-sectional side views of various stages of manufacturing the semiconductor device structure taken along line G-G of FIG. 21A, after the semiconductor device structure is flipped over, in accordance with some embodiments.

FIGS. 24C-26C are cross-sectional side views of various stages of manufacturing the semiconductor device structure taken along line H-H of FIG. 21A, after the semiconductor device structure is flipped over, in accordance with some embodiments.

FIG. 27 is a top view of the semiconductor device structure 100 showing the location of a conductive feature, in accordance with some embodiments.

FIGS. 28A-30A are cross-sectional side views of various stages of manufacturing the semiconductor device structure taken along line A-A of FIG. 6, in accordance with alternative embodiments.

FIGS. 28B-30B are cross-sectional side views of various stages of manufacturing the semiconductor device structure taken along line B-B of FIG. 6, in accordance with some embodiments.

FIGS. 28C-30C are cross-sectional side views of various stages of manufacturing the semiconductor device structure taken along line C-C of FIG. 6, in accordance with alternative embodiments.

FIG. 31 is a top view of the semiconductor device structure shown in FIGS. 30A, 30B, and 30C, in accordance with some embodiments.

FIGS. 32A, 32B, 32C, 32D are various views of one of various stages of manufacturing the semiconductor device structure, in accordance with alternative embodiments.

FIGS. 33A, 33B, 33C, 33D are various views of one of various stages of manufacturing the semiconductor device structure, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide semiconductor device structures having power network moved from the front-side to the backside. As a result, the routing resource for both backside power and front-side signal is relaxed.

While the embodiments of this disclosure are discussed with respect to nanostructure channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

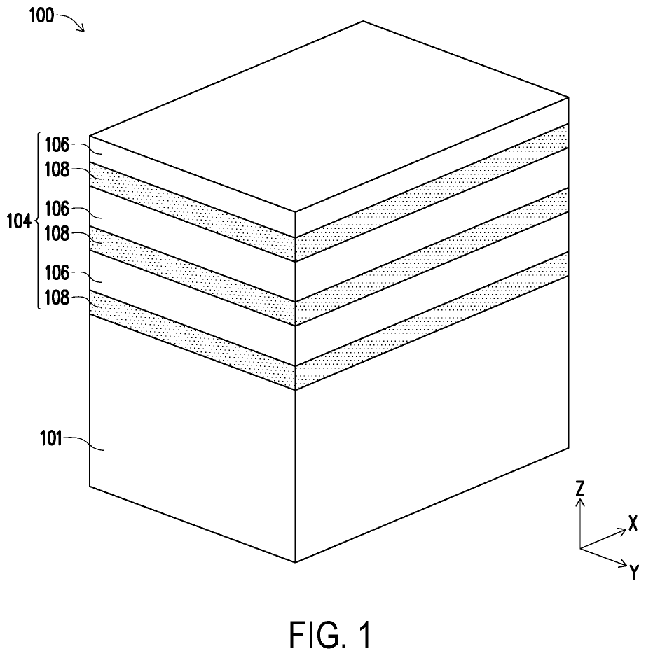

FIGS. 1-27 show exemplary processes for manufacturing a semiconductor device structure 100 according to embodiments of the present disclosure. It is understood that additional operations can be provided before, during, and after processes shown by FIGS. 1-27, and some of the operations described below can be replaced or eliminated, for additional embodiments of the method. The order of the operations/processes is not limiting and may be interchangeable.

FIGS. 1-6 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

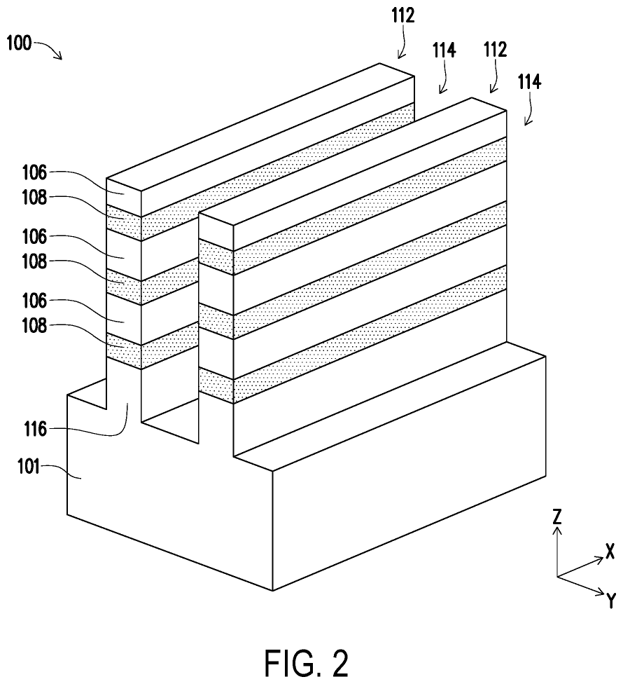

In FIG. 2, fin structures 112 are formed from the stack of semiconductor layers 104. Each fin structure 112 has an upper portion including the semiconductor layers 106, 108 and a well portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

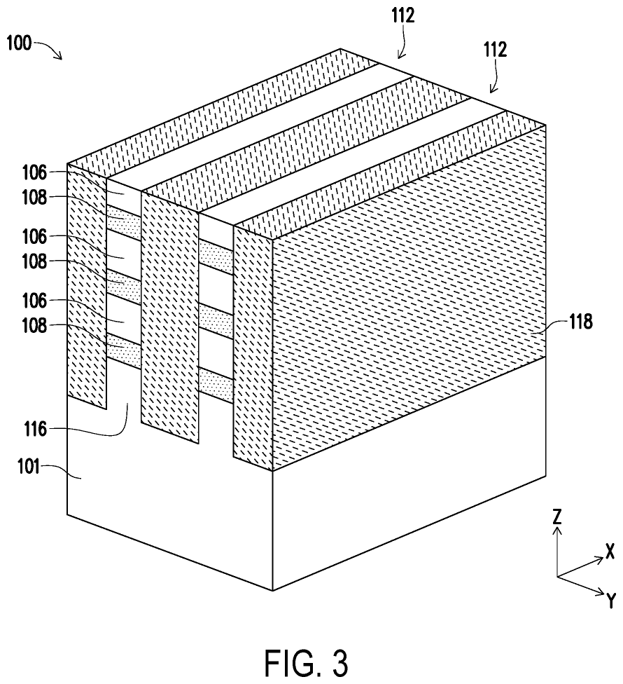

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

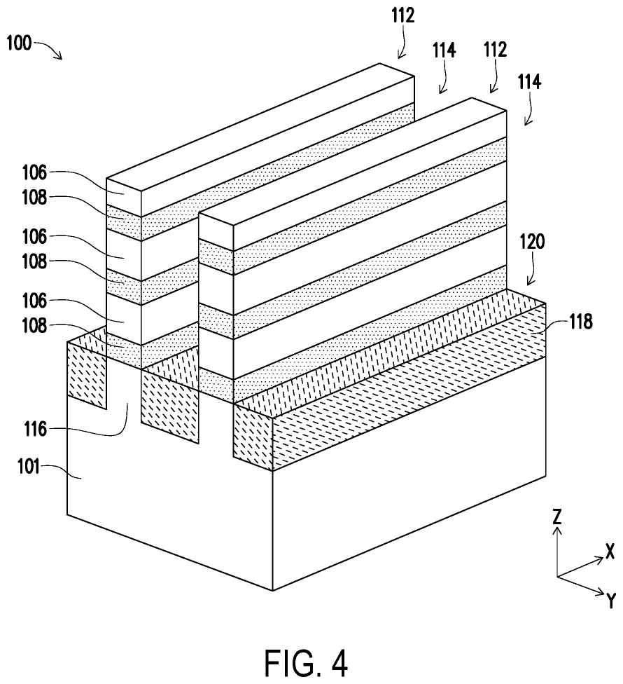

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the well portion 116 formed from the substrate 101.

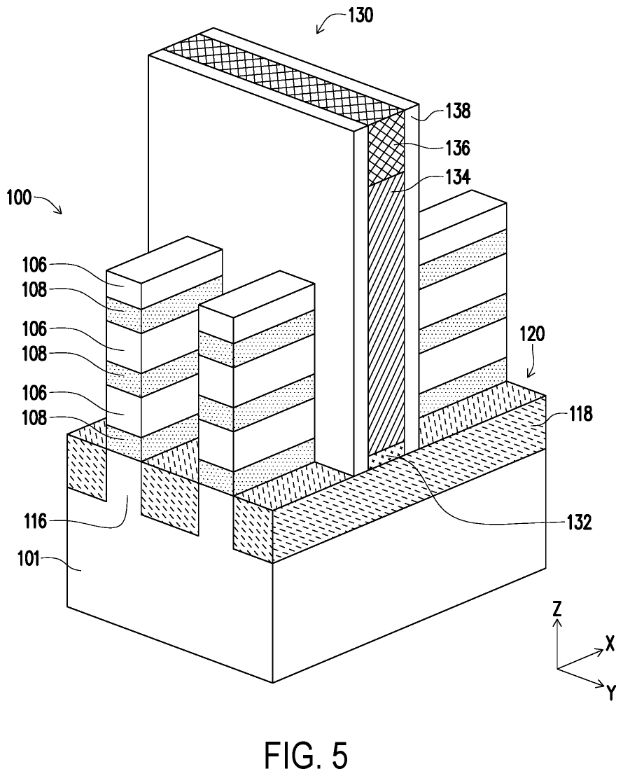

In FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. In some embodiments, the gate spacers 138 are also formed on the sidewalls of the exposed portions of the fin structures 112. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 of the sacrificial gate structure 130 serve as channel regions for the semiconductor device structure 100.

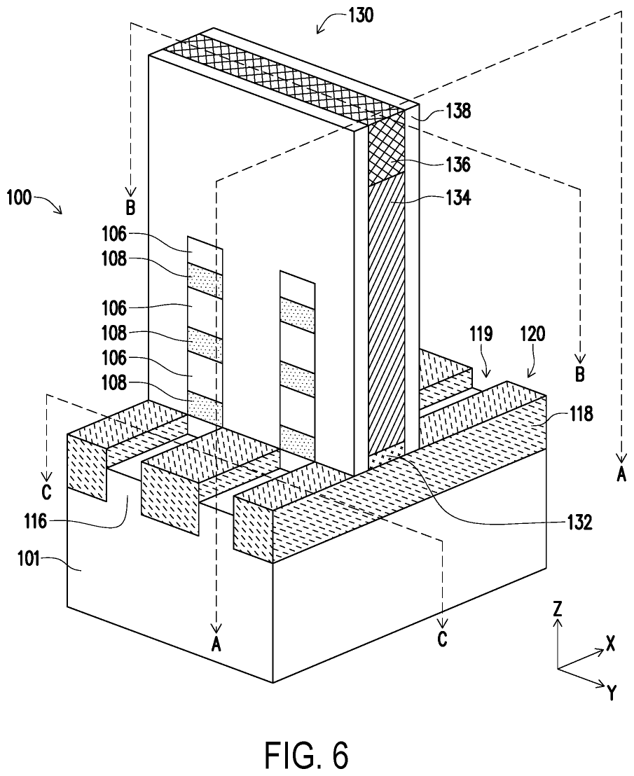

In FIG. 6, the portions of the fin structures 112 not covered by the sacrificial gate structure 130 and the gate spacers 138 are recessed to a level above, at, or below the top surfaces of the isolation regions 120. The recess of the portions of the fin structures 112 can be done by an etch process, either isotropic or anisotropic etch process, and the etch process may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant.

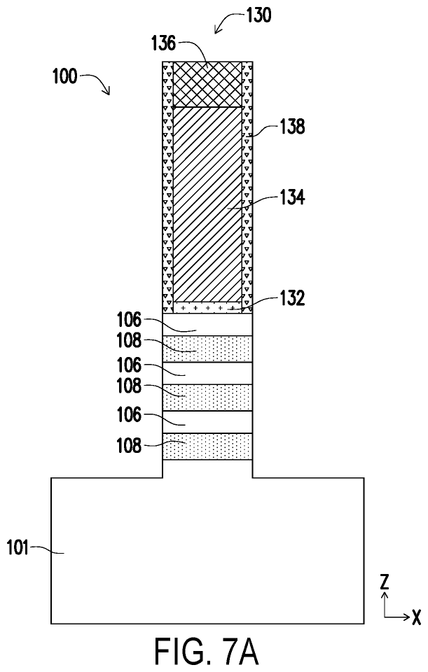

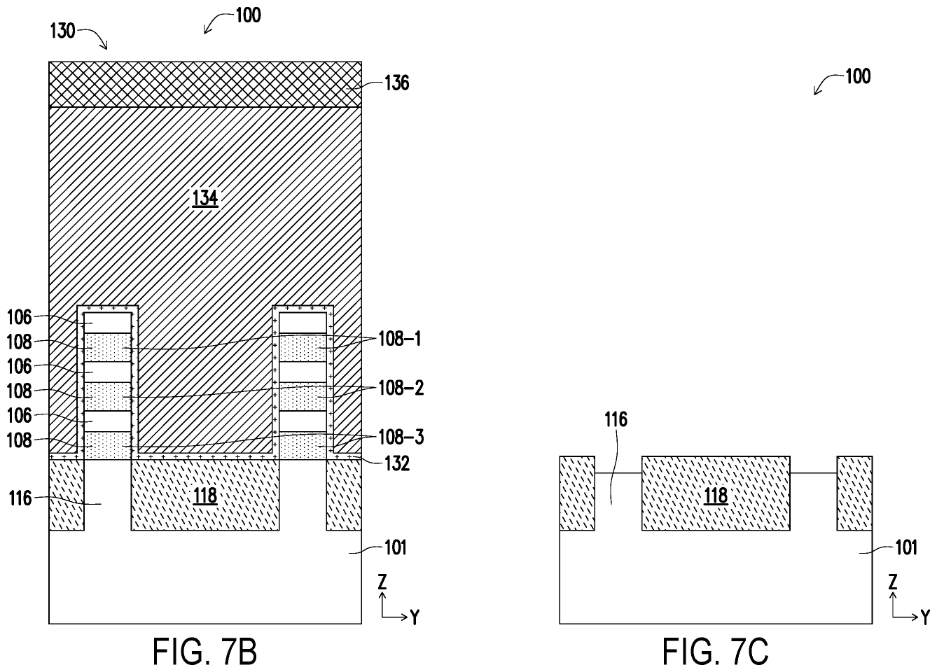

FIGS. 7A, 7B, and 7C are cross-sectional side views of the semiconductor device structure 100 taken along line A-A, line B-B, and line C-C of FIG. 6, respectively.

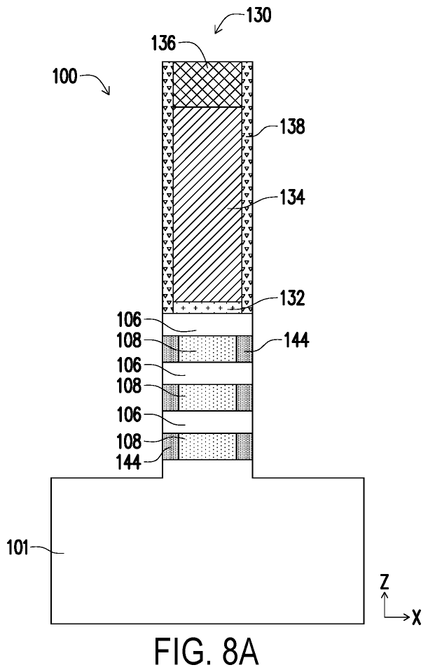

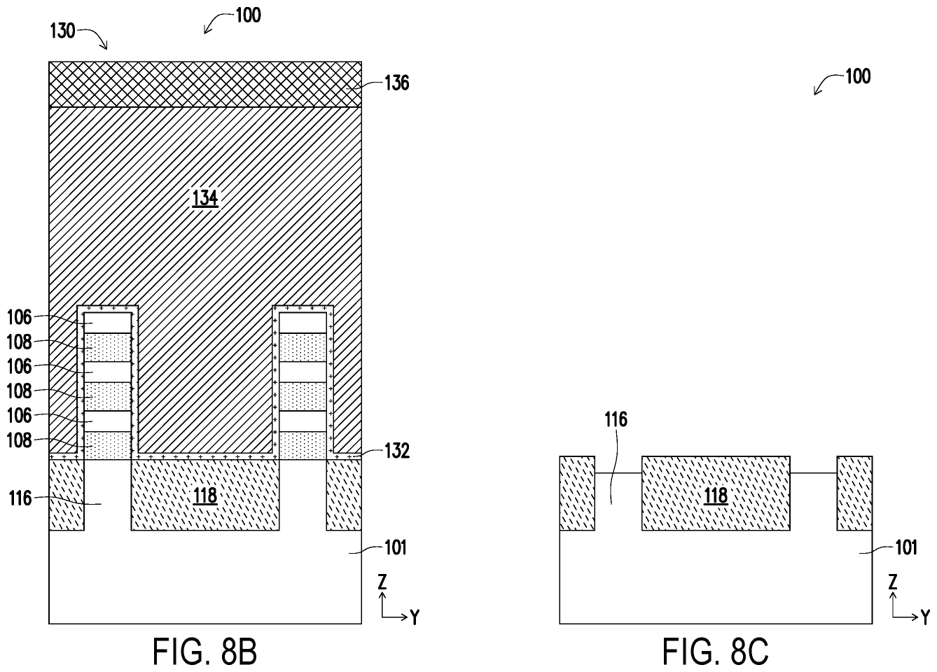

FIGS. 8A, 8B, and 8C are cross-sectional side views of one of various stages of manufacturing the semiconductor device structure 100 taken along line A-A, line B-B, and line C-C of FIG. 6, respectively, in accordance with some embodiments. As shown in FIG. 8A, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

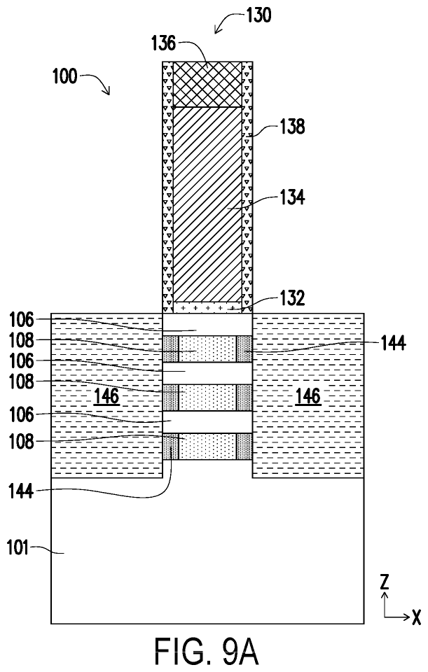

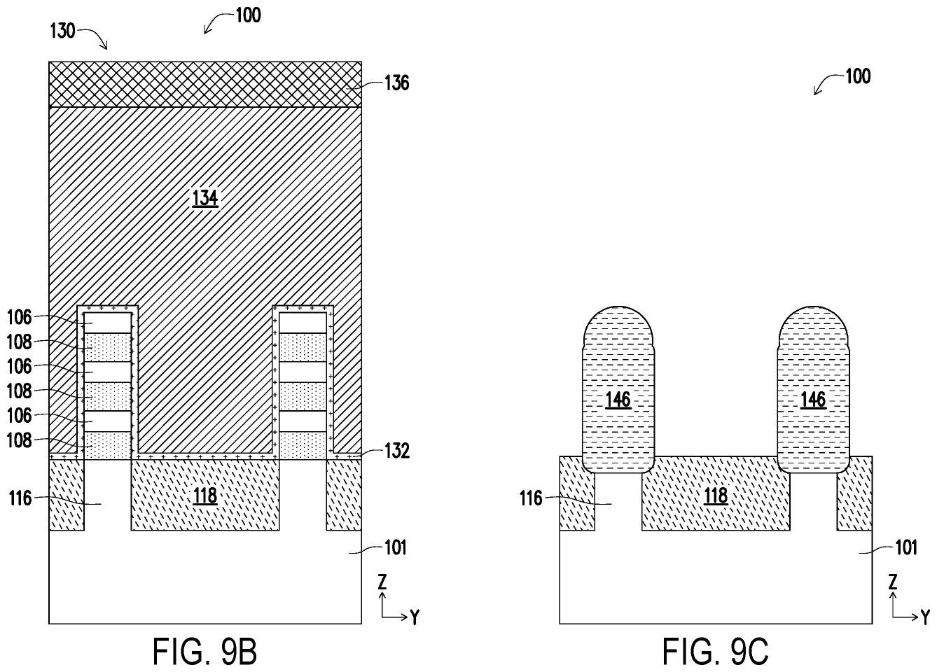

FIGS. 9A, 9B, and 9C are cross-sectional side views of one of various stages of manufacturing the semiconductor device structure 100 taken along line A-A, line B-B, and line C-C of FIG. 6, respectively, in accordance with some embodiments. As shown in FIGS. 9A and 9C, source/drain (S/D) regions 146 are formed from the well portions 116. In some embodiments, the S/D regions 146 may grow both vertically and horizontally to form facets, which may correspond to crystalline planes of the material used for the well portion 116. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or one or more layers of Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE.

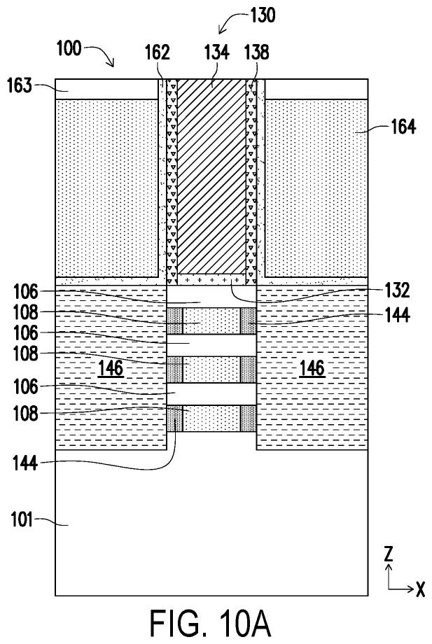

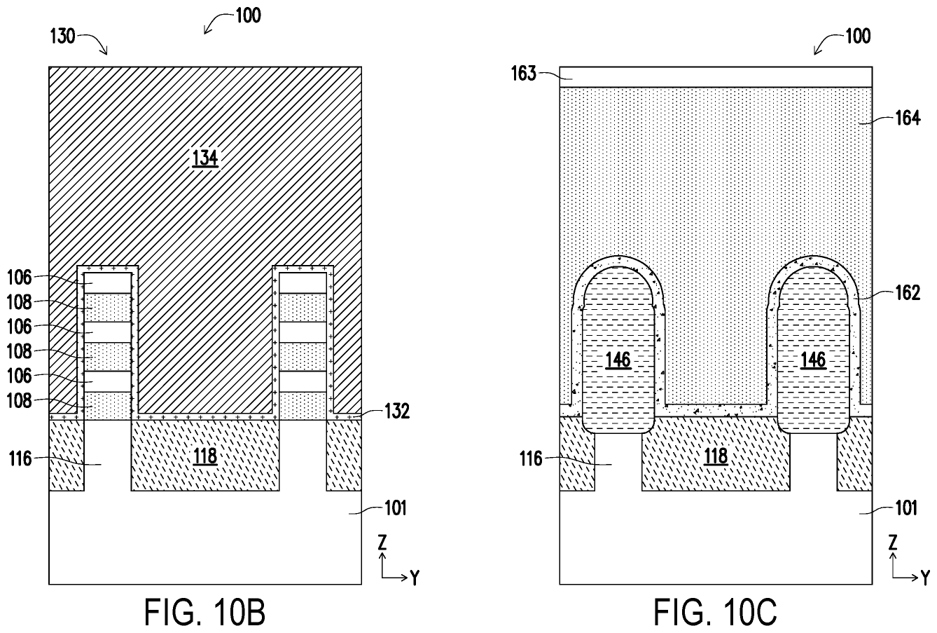

FIGS. 10A, 10B, and 10C are cross-sectional side views of one of various stages of manufacturing the semiconductor device structure 100 taken along line A-A, line B-B, and line C-C of FIG. 6, respectively, in accordance with some embodiments. In FIGS. 10A, 10B, and 10C, a contact etch stop layer (CESL) 162 is conformally formed on the exposed surfaces of the semiconductor device structure 100. The CESL 162 covers the sidewalls of the sacrificial gate structure 130, the insulating material 118, and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to cure the ILD layer 164.

After the ILD layer 164 is formed, a planarization operation, such as CMP, is performed on the semiconductor device structure 100 until the sacrificial gate electrode layer 134 is exposed, as shown in FIGS. 10A and 10B. In some embodiments, after the planarization process, the ILD layer 164 is recessed, and a dielectric layer 163 is formed on the recessed ILD layer 164. The dielectric layer 163 may include a nitride, such as silicon nitride, to protect the ILD layer 164 during subsequent processes. A second planarization process may be performed to remove portions of the dielectric layer 163 formed on the sacrificial gate electrode layer 134.

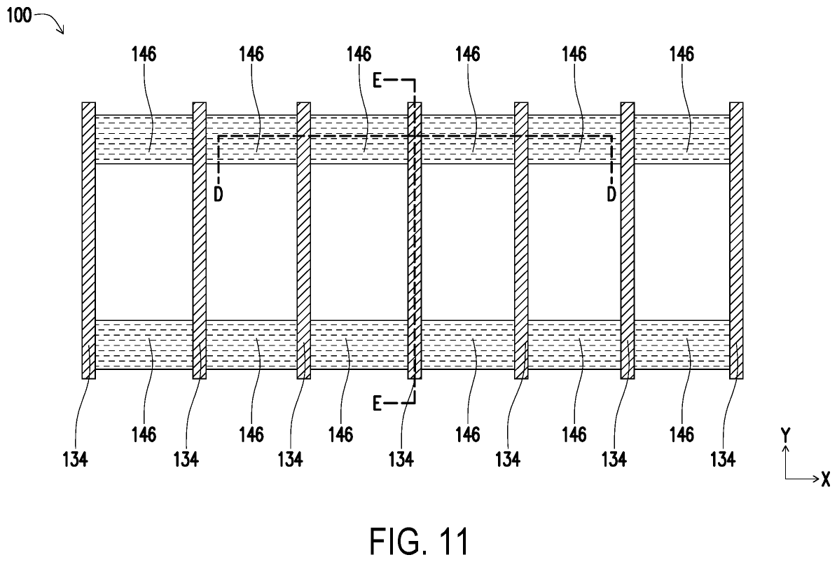

FIG. 11 is a top view of the semiconductor device structure 100 shown in FIGS. 10A, 10B, 10C, in accordance with some embodiments. Some components of the semiconductor device structure 100, such as the dielectric layer 163 and the CESL 162, are omitted in FIG. 11 for clarity. As shown in FIG. 11, the semiconductor device structure 100 includes S/D regions 146 formed on opposite sides of the sacrificial gate electrode layer 134.

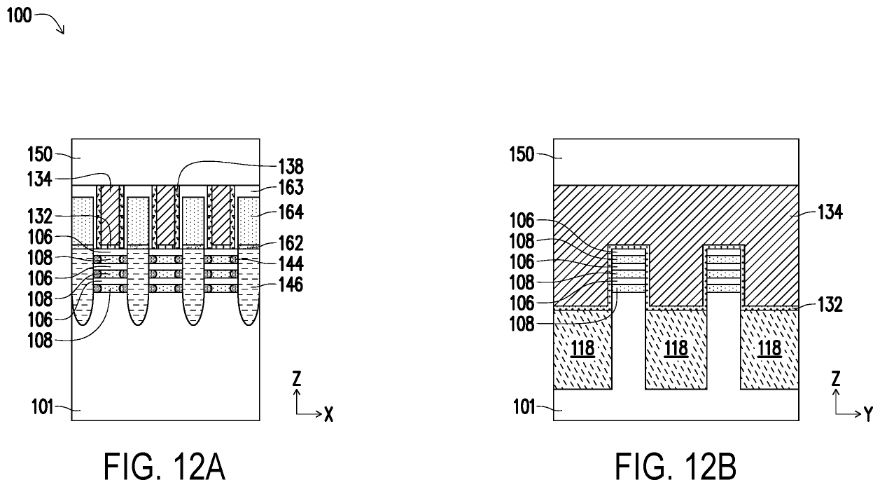

FIGS. 12A-18A are cross-sectional side views of various stages of manufacturing the semiconductor device structure 100 taken along line D-D of FIG. 11, in accordance with some embodiments. FIGS. 12B-18B are cross-sectional side views of various stages of manufacturing the semiconductor device structure 100 taken along line E-E of FIG. 11, in accordance with some embodiments. As shown in FIGS. 12A and 12B, a mask layer 150 is formed on the dielectric layer 163 and the sacrificial gate electrode layer 134. The mask layer 150 may include a dielectric layer, such as SiN.

In FIGS. 13A and 13B, a mask structure 152 is formed on the mask layer 150. In some embodiments, the mask structure 152 is a tri-layer photoresist. For example, the mask structure 152 may include a bottom layer 154 and a middle layer 156 disposed on the bottom layer 154. The bottom layer 154 and the middle layer 156 are made of different materials such that the optical properties and/or etching properties of the bottom layer 154 and the middle layer 156 are different from each other. In some embodiments, the bottom layer 154 may be a carbon layer, and the middle layer 156 may be a silicon-rich layer designed to provide an etch selectivity between the middle layer 156 and the bottom layer 154. The mask structure 152 further includes a photoresist layer 158 that may be a chemically amplified photoresist layer and can be a positive tone photoresist or a negative tone photoresist. The photoresist layer 158 may include a polymer, such as phenol formaldehyde resin, a poly(norbornene)-co-malaic anhydride (COMA) polymer, a poly(4-hydroxystyrene) (PHS) polymer, a phenol-formaldehyde (bakelite) polymer, a polyethylene (PE) polymer, a polypropylene (PP) polymer, a polycarbonate polymer, a polyester polymer, or an acrylate-based polymer, such as a poly (methyl methacrylate) (PMMA) polymer or poly (methacrylic acid) (PMAA). The photoresist layer 158 may be formed by spin-on coating. The photoresist layer 158 may be patterned to have openings 160 formed therein.

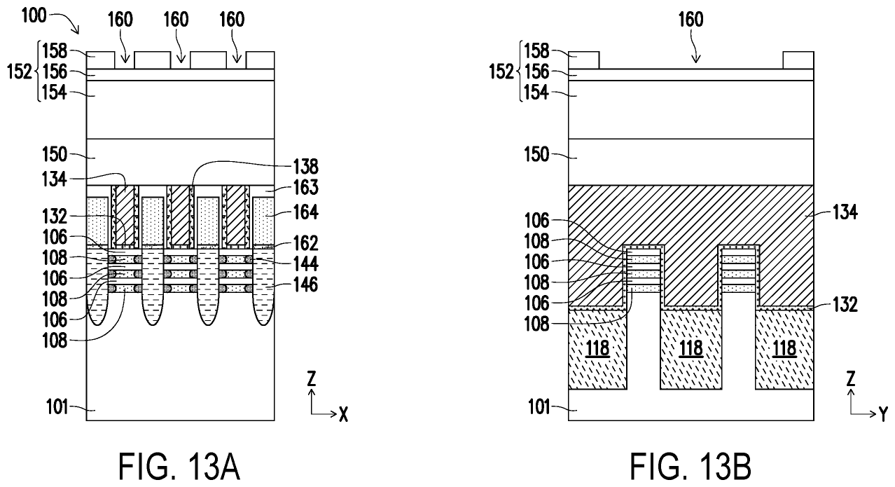

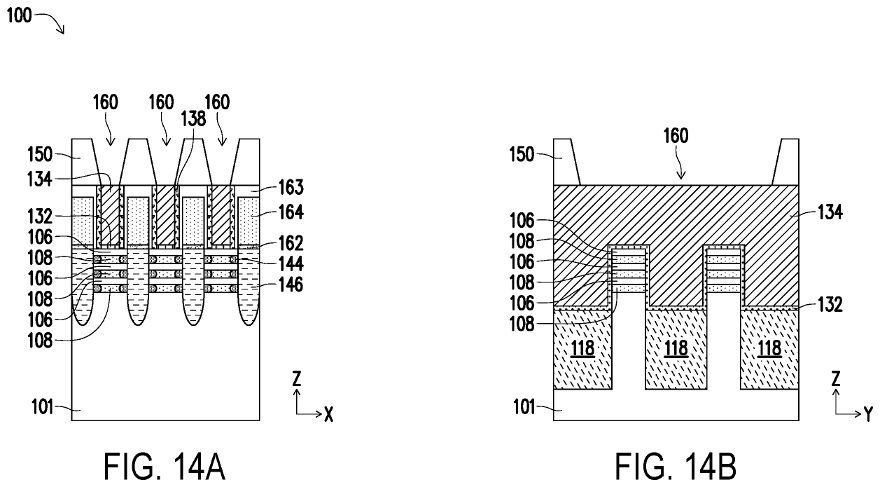

In FIGS. 14A and 14B, the openings 160 are extended into the middle layer 156, the bottom layer 154, and the mask layer 150. The mask structure 152 may be removed after the openings 160 are extended into the mask layer 150. In some embodiments, portions of the sacrificial gate electrode layers 134 are exposed in the openings 160.

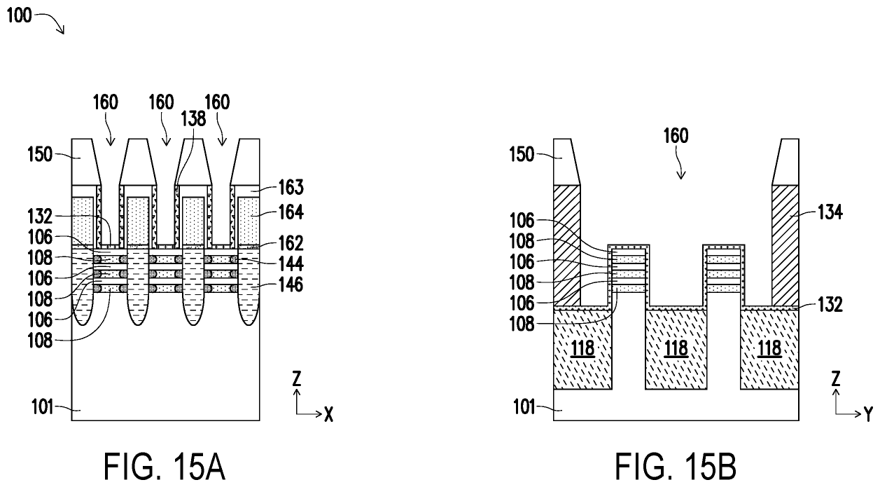

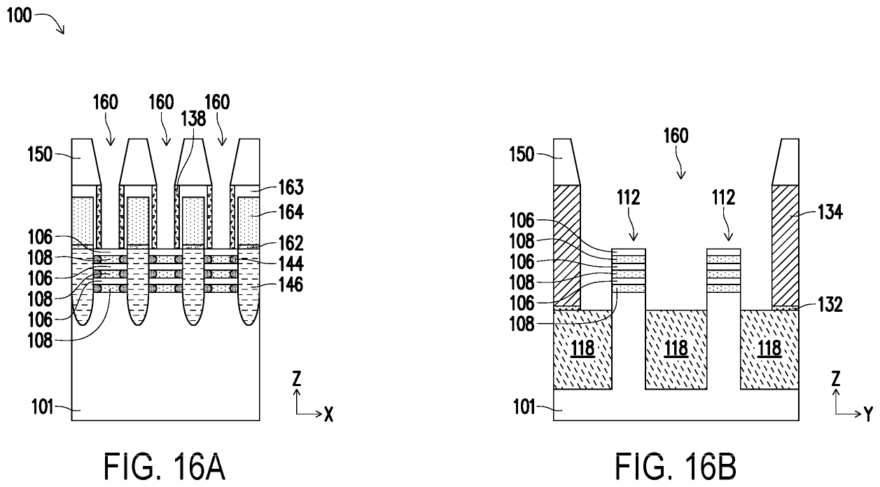

In FIGS. 15A and 15B, the exposed portions of the sacrificial gate electrode layers 134 are removed. The exposed portions of the sacrificial gate electrode layers 134 may be removed by an etch process, such as a selective etch process that does not substantially affect the mask layer 150 and the sacrificial gate dielectric layer 132. In FIGS. 16A and 16B, the exposed portions of the sacrificial gate dielectric layer 132 are removed, and portions of the fin structures 112 are exposed.

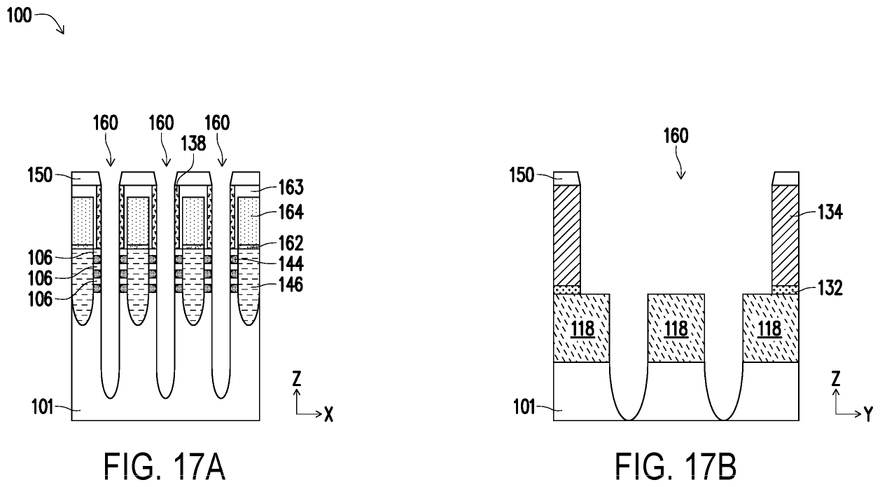

In FIGS. 17A and 17B, the exposed portions of the fin structures 112 are removed. The exposed portions of the fin structures 112 may be removed by one or more etch processes. In some embodiments, the one or more etch processes may be selective etch processes that do not substantially affect the dielectric materials of the mask layer 150, the dielectric spacers 144, and the insulating material 118. In some embodiments, the one or more etch processes may be anisotropic etch processes, and portions of the first semiconductor layers 106 under the gate spacers 138 and dielectric spacers 144 may remain, as shown in FIG. 17A. As shown in FIGS. 17A and 17B, the openings 160 extend into the substrate 101.

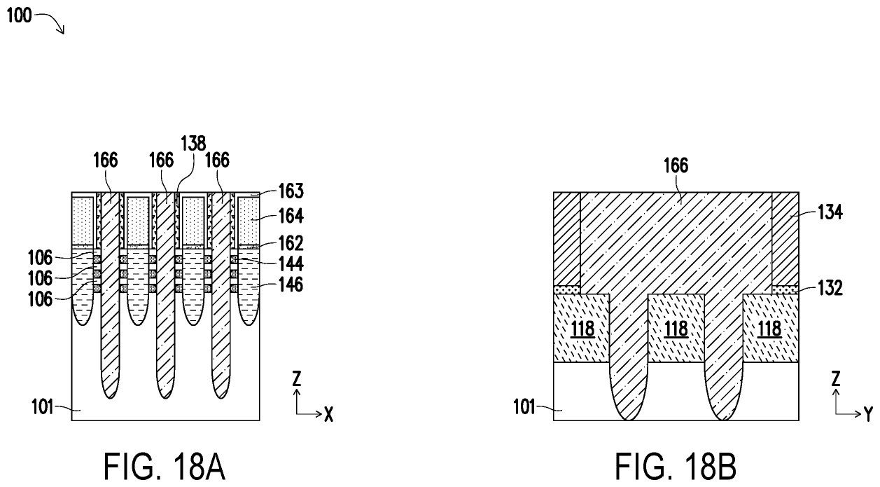

In FIGS. 18A and 18B, a dielectric layer 166 is formed in the openings 160. The dielectric layer 166 may include any suitable dielectric material. In some embodiments, the dielectric layer 166 includes SiN. The dielectric layer 166 may be also formed on the dielectric layer 163, and a planarization process, such as a CMP process, may be performed to remove portions of the dielectric layer 166 formed on the dielectric layer 163. The CMP process may also remove the mask layer 150.

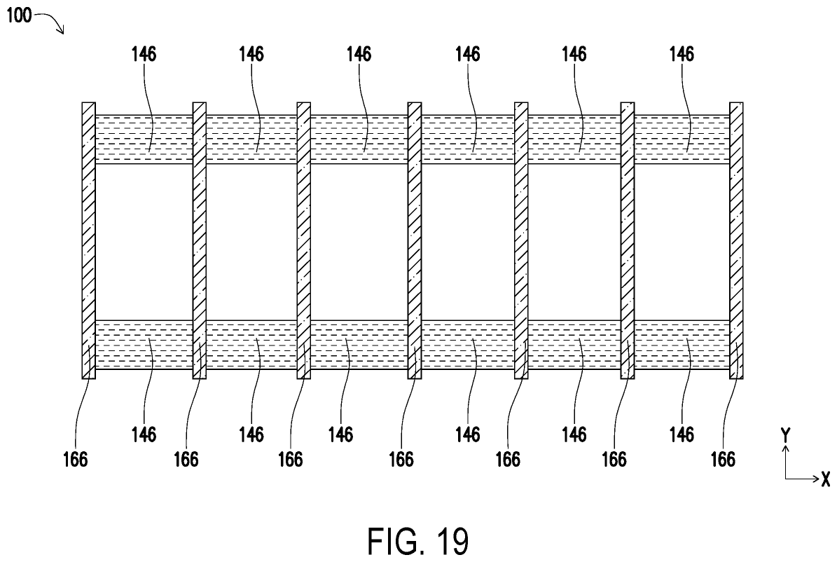

FIG. 19 is a top view of the semiconductor device structure 100 shown in FIGS. 18A and 18B, in accordance with some embodiments. Some components of the semiconductor device structure 100, such as the dielectric layer 163 and the CESL 162, are omitted in FIG. 19 for clarity. As shown in FIG. 19, portions of the sacrificial gate electrode layers 134 are replaced by the dielectric layers 166. The processes described in FIGS. 12A to 18B may be referred to as a continuous polysilicon on diffusion (CPODE) process, which is to form an isolation region that divide active region into multiple segments. The region shown in FIG. 19 may be an isolation region, the channels (the fin structures 112 shown in FIGS. 12B) and the portions of the sacrificial gate electrode layers 134 are removed and replaced with the dielectric layers 166, and the S/D regions 146 on opposite sides of the dielectric layers 166 are dummy S/D regions. In some embodiments, the dielectric layers 166 are substantially parallel to each other, as shown in FIG. 19. The semiconductor device structure 100 may include active regions (not shown in FIG. 19), such as active S/D regions 146 located over and below the S/D regions 146 shown in FIG. 19, and portions of the sacrificial gate electrode layers 134 disposed across the active S/D regions 146, such as the portions of the sacrificial gate electrode layers 134 shown in FIG. 18B. During the formation of the dielectric layers 166, the portions of the sacrificial gate electrode layers 134 in the active regions are covered by the mask layer 150.

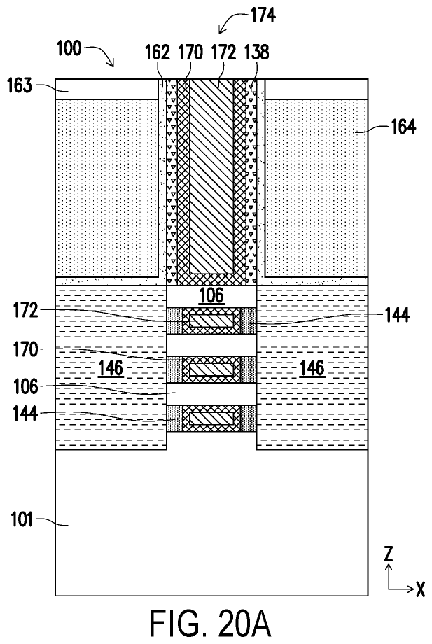

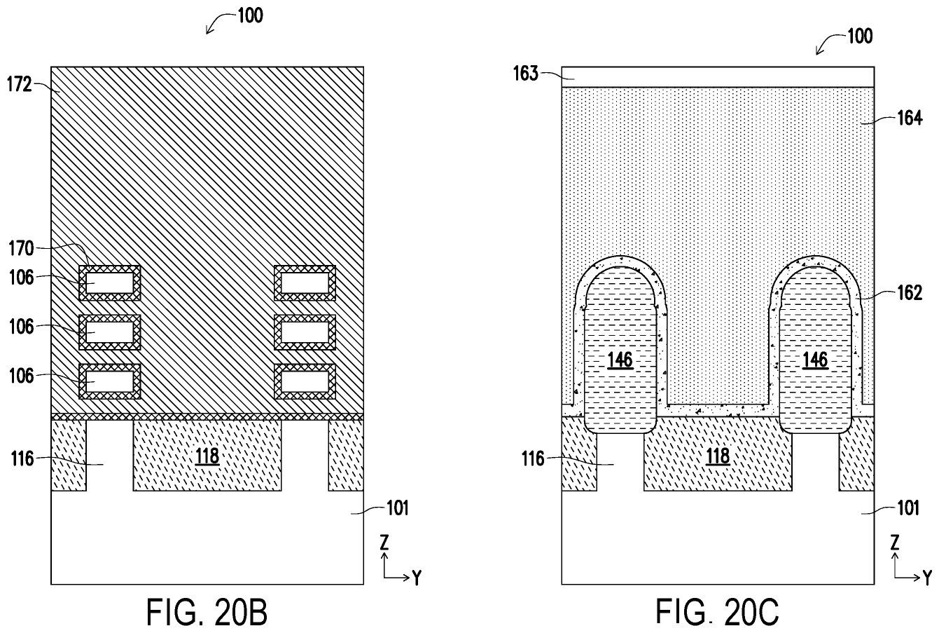

FIGS. 20A, 20B, 20C are various views of one of various stages of manufacturing the semiconductor device structure 100, in accordance with some embodiments. In the active regions, the semiconductor device structure 100 may have various views shown in FIGS. 10A, 10B, 10C after the formation of the dielectric layers 166 in the isolation region. Next, the sacrificial gate structures 130 and the second semiconductor layers 108 are replaced with the gate dielectric layers 170 and the gate electrode layers 172. The removal of the sacrificial gate structure 130 and the semiconductor layers 108 forms an opening between gate spacers 138 and between first semiconductor layers 106. The dielectric materials of the dielectric layers 163 and the dielectric layers 166 are not substantially affected by the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the dielectric layers 166, the dielectric layer 163, and the CESL 162.

Portions of the second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the gate spacers 138, the dielectric layers 166, the dielectric layers 163, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

After the formation of the nanostructure channels (i.e., the exposed portions of the first semiconductor layers 106), the gate dielectric layer 170 is formed to surround the exposed portions of the first semiconductor layers 106, and the gate electrode layer 172 is formed on the gate dielectric layer 170. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the sacrificial dielectric layer 164. The gate dielectric layer 170 and the gate electrode layer 172 formed over the sacrificial dielectric layer 164 are then removed by using, for example, CMP, until the top surface of the sacrificial dielectric layer 164 is exposed.

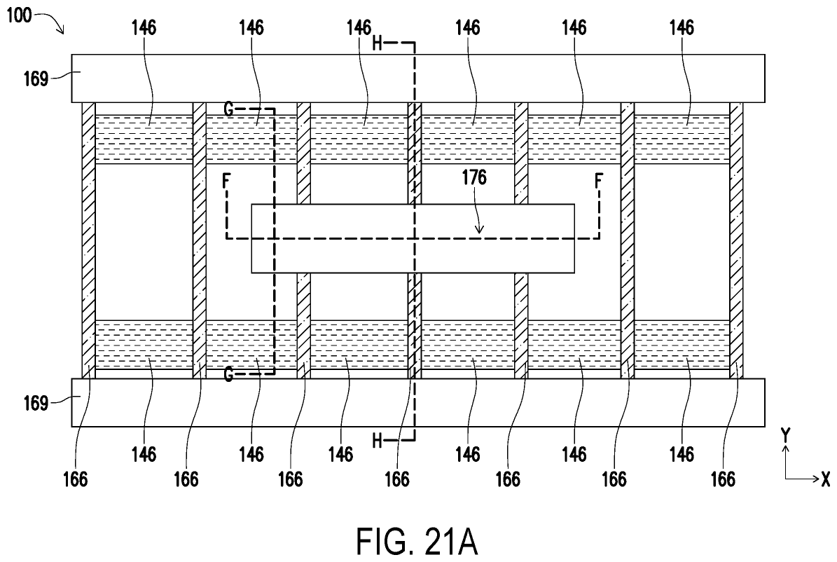

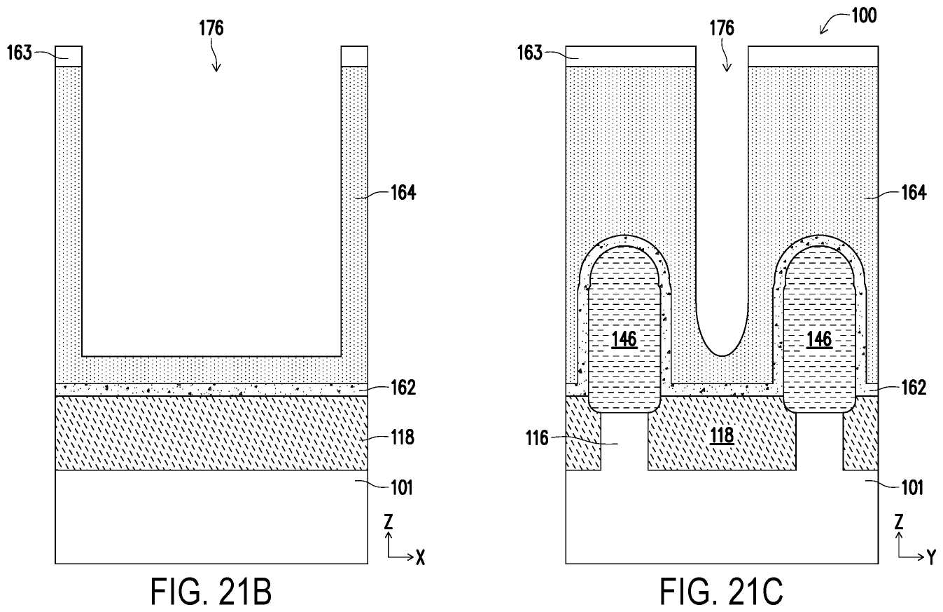

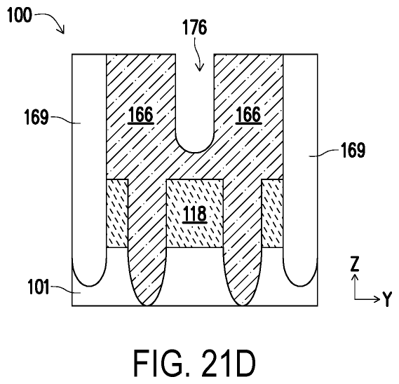

FIGS. 21A, 21B, 21C, 21D are various views of one of various stages of manufacturing the semiconductor device structure 100, in accordance with some embodiments. FIG. 21A is a top view of the isolation region of the semiconductor device structure 100, FIGS. 21B, 21C, 21D are cross-sectional side views of the semiconductor device structure 100 taken along lines F-F, G-G, H—H of FIG. 21A, respectively. In some embodiments, after the formation of the gate structure 174, a cut metal gate (CMG) process may be performed to separate the gate electrode layer 172 in the active regions into two or more segments. Each segment of the gate electrode layer 172 functions as a gate electrode layer for an individual transistor. The CMG process may include forming a trench in the gate electrode layer 172 and the gate dielectric layer 170 and filling the trench with a dielectric layer, such as a SiN layer. After filling the trench with the dielectric layer, a planarization process, such as a CMP process, may be performed to remove portions of the dielectric layer other than those in the trench. As shown in FIGS. 21A, 21B, 21C, 21D, in some embodiments, dielectric layers 169 are formed at the borders of the isolation region. As a result, the dielectric layers 166 and the gate electrode layers 172 are separated by the dielectric layers 169. Next, contact openings 176 are formed in the active regions to expose active S/D regions 146. A contact opening 176 may be also formed in the isolation region, as shown in FIGS. 21A. A patterned mask layer (not shown) may be first formed on the semiconductor device structure 100, and the pattern is transferred to the dielectric layer 163 and the ILD layer 164. In other words, portions of the dielectric layer 163 and the ILD layer 164 not covered by the patterned mask layer are removed. Portions of the CESL 162 located in the active regions are also removed to expose the active S/D regions 146.

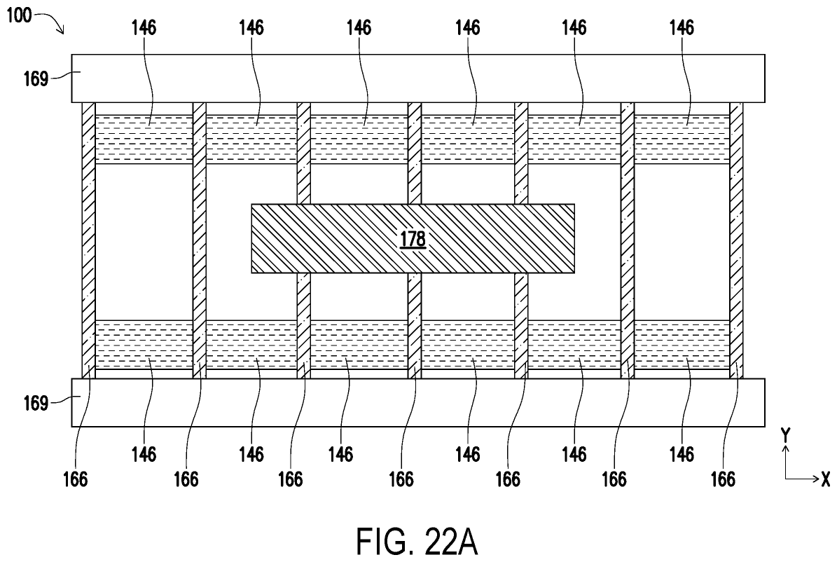

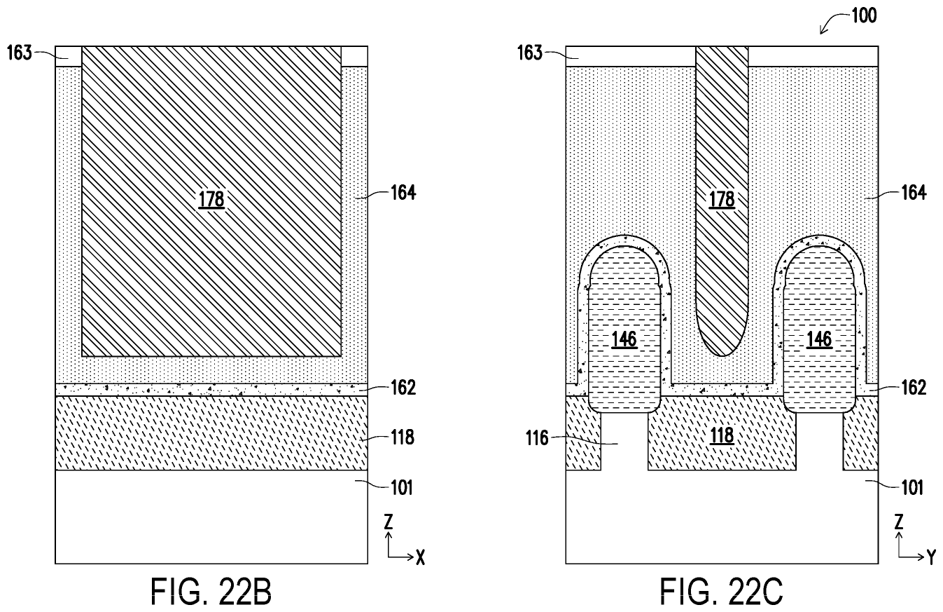

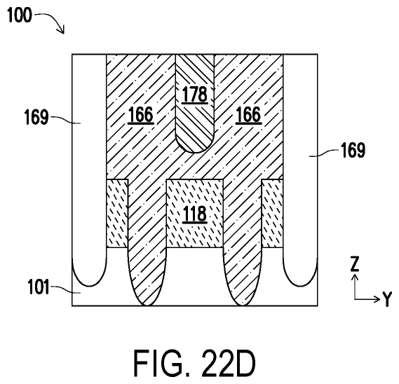

FIGS. 22A, 22B, 22C, 22D are various views of one of various stages of manufacturing the semiconductor device structure 100, in accordance with some embodiments. FIG. 22A is a top view of the isolation region of the semiconductor device structure 100, FIGS. 22B, 22C, 22D are cross-sectional side views of the semiconductor device structure 100 taken along lines F-F, G-G, H—H of FIG. 21A, respectively. As shown in FIGS. 22A to 22D, a conductive contact 178 is formed in opening 176 in the isolation region of the semiconductor device structure 100. The conductive contact 178 may be electrically conductive and may include a material having one or more of Ru, Mo, Co, Ni. W, Ti, Ta, Cu, Al, TiN or TaN, and the conductive contact 178 may be formed by any suitable method, such as electro-chemical plating (ECP), or PVD.

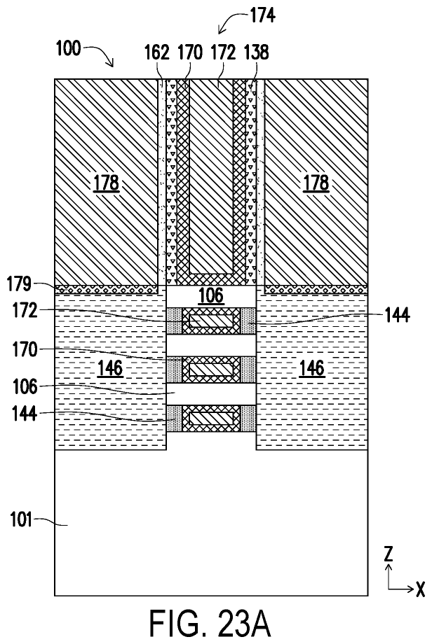

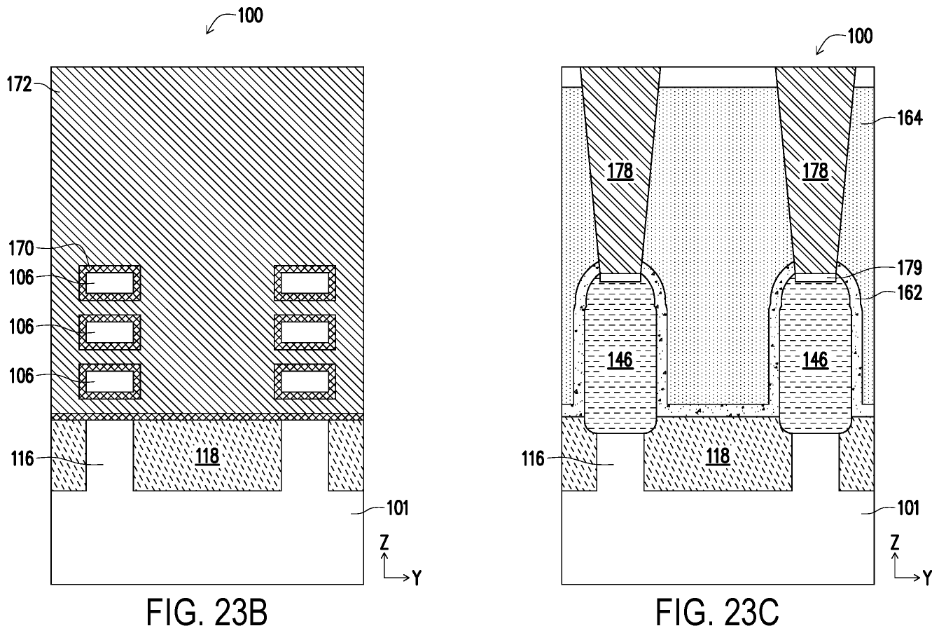

FIGS. 23A, 23B, 23C are various views of one of various stages of manufacturing the semiconductor device structure 100, in accordance with some embodiments. In the active regions of the semiconductor device structure 100, the contact openings are formed in the dielectric layer 163, the ILD layer 164, and the CESL 162 to expose the active S/D regions 146, and the conductive contacts 178 are formed in the contact openings. The contact openings and the conductive contacts 178 are formed simultaneously in the active regions and the isolation region. A silicide layer 179 may be disposed between the conductive contact 178 and corresponding S/D region 146, as shown in FIGS. 23A and 23C. The silicide layer 179 may include a material having one or more of WSi, CoSi, NiSi, TiSi, MoSi and TaSi.

It is understood that the semiconductor device structure 100 may undergo further processes to form conductive contacts to be electrically connected to the gate electrode layers 172. An interconnect structure may be formed over the semiconductor device structure 100 to provide electrical paths to the devices formed on the substrate 101. In some embodiments, a conductive feature, such as a conductive line, is formed in the interconnect structure and electrically connect the conductive contact 178 located in the isolation region and one or more conductive contacts 178 located in the active regions. After completing the interconnect structure, which includes multiple layers of conductive features, such as conductive vias and conductive lines, embedded in intermetal dielectric (IMD) layers, the semiconductor device structure 100 is flipped over for backside processing.

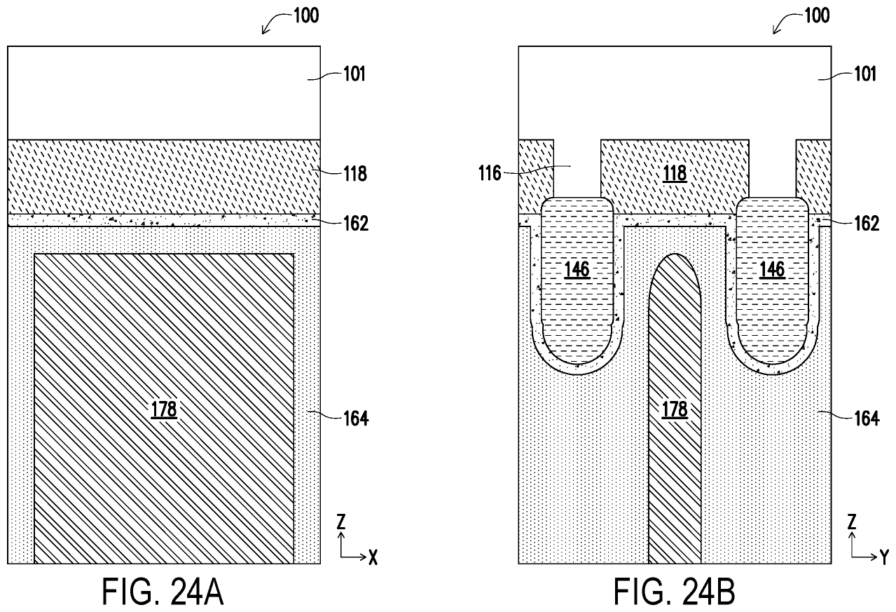

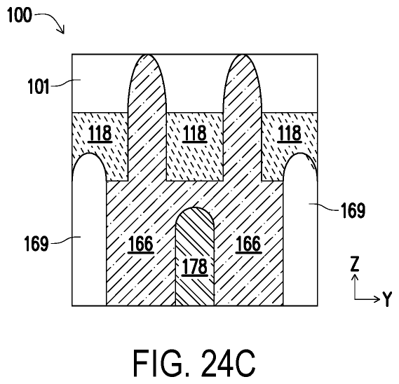

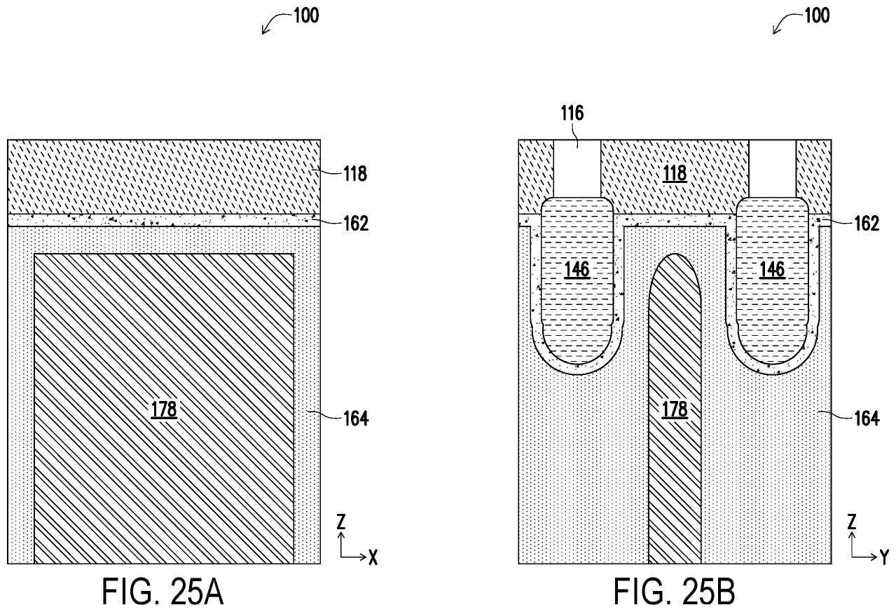

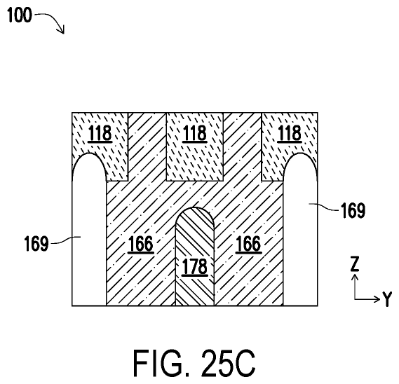

FIGS. 24A-26A are cross-sectional side views of various stages of manufacturing the semiconductor device structure 100 taken along line F-F of FIG. 21A, after the semiconductor device structure 100 is flipped over, in accordance with some embodiments. FIGS. 24B-26B are cross-sectional side views of various stages of manufacturing the semiconductor device structure 100 taken along line G-G of FIG. 21A, after the semiconductor device structure 100 is flipped over, in accordance with some embodiments. FIGS. 24C-26C are cross-sectional side views of various stages of manufacturing the semiconductor device structure 100 taken along line H-H of FIG. 21A, after the semiconductor device structure 100 is flipped over, in accordance with some embodiments. The interconnect structure formed on the semiconductor device structure 100 is omitted for clarity in the above-mentioned figures. As shown in FIGS. 24A, 24B, 24C, the semiconductor device structure 100 is flipped over for backside processing. Next, as shown in FIGS. 25A, 25B, 25C, the substrate 101 is thinned down, and the insulating material 118, the well portion 116, and the dielectric material 137 are exposed. In some embodiments, the dielectric layers 166 are also exposed. The thinning down of the substrate 101 may be by any suitable process. In some embodiments, a planarization process, such as a CMP process, is performed to thin down the substrate 101.

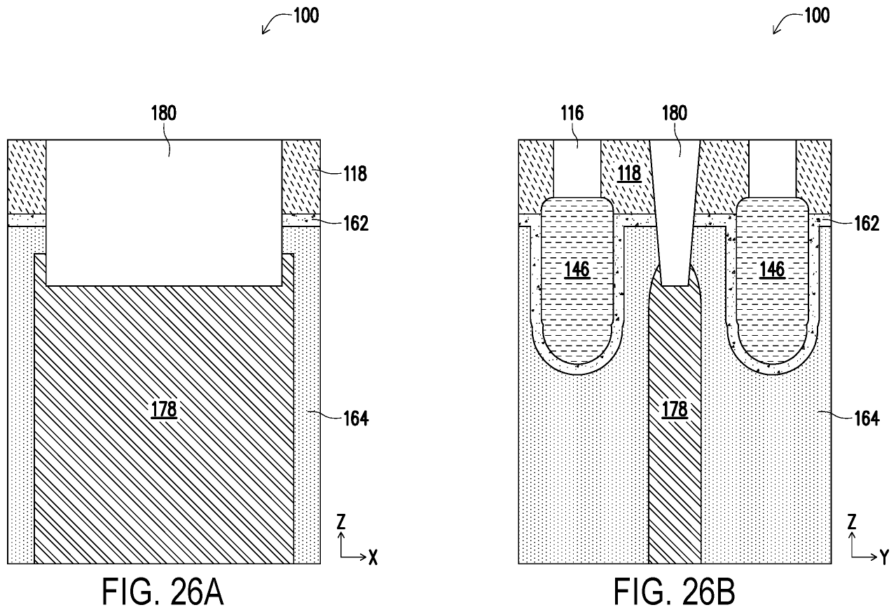

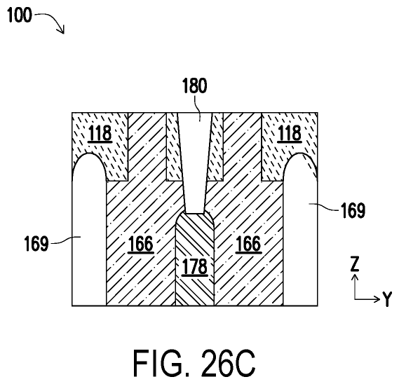

Next, as shown in FIGS. 26A, 26B, 26C, a conductive feature 180 is formed in the insulating material 118, the CESL 162, the ILD layer 164, and the dielectric layers 166. The conductive feature 180 may include an electrically conductive material, such as copper, aluminum, aluminum copper alloy, titanium, titanium nitride, tantalum, tantalum nitride, titanium silicon nitride, zirconium, gold, silver, cobalt, nickel, tungsten, tungsten nitride, tungsten silicon nitride, platinum, chromium, molybdenum, hafnium, other suitable conductive material, or a combination thereof. The conductive feature 180 is formed by any suitable process, such as PVD, CVD, or ECP. In some embodiments, a patterned mask layer (not shown) is first formed on the semiconductor device structure 100, and the patterned mask layer exposes portions of the insulating material 118. Then, the exposed portions of the insulating material 118 are removed by one or more etch processes. The one or more etch processes also removes portions of the CESL 162, the ILD layer 164, and the dielectric layers 166 located under the exposed portions of the insulating material 118 until the conductive feature 178 located in the isolation region is exposed in an opening formed in the insulating material 118, the CESL 162, the ILD layer 164, and the dielectric layers 166. In some embodiments, a portion of the conductive feature 178 is also removed by the one or more etch processes. Next, the conductive feature 180 is formed in the opening and is electrically connected to the conductive feature 178. In some embodiments, the conductive feature 180 extends into the conductive feature 178, as shown in FIGS. 26A, 26B, 26C. The conductive feature 180 is electrically connected to the conductive contact 178 in the isolation region, which is electrically connected to one or more conductive contacts 178 in the active regions via the conductive feature located in the front side interconnect structure. Thus, power may be supplied to the active S/D regions 146 from the backside via the conductive feature 180. As a result, metal routing efficiency is improved. A planarization process, such as a CMP process, may be performed to remove the portion of the conductive feature 180 formed on the mask layer. The planarization process may also remove the mask layer, and the conductive feature 180, insulating material 118, and the well portions 116 are exposed and have a substantially co-planar top surface.

Subsequent processes may include forming an interconnect structure on the backside of the semiconductor device structure 100. The interconnect structure may include a conductive feature, such as a conductive line, electrically connected to the conductive feature 180 to provide power to the conductive feature 180.

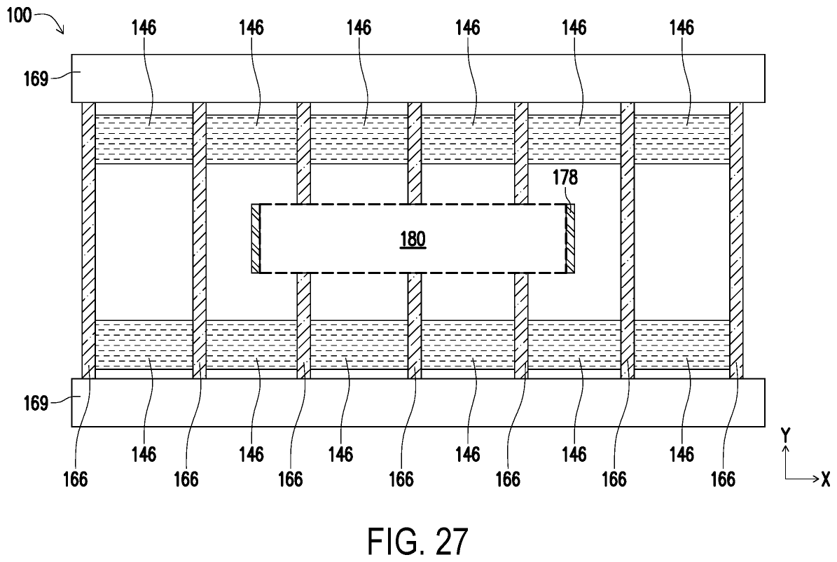

FIG. 27 is a top view of the semiconductor device structure 100 shown in FIG. 22A after the formation of the conductive feature 180. The conductive feature 180 is shown in FIG. 27 in dotted lines because the conductive feature 180 would not be seen in a top view (after the semiconductor device structure 100 is flipped back so the front side is the top). As shown in FIG. 27, the conductive contact 178 and the conductive feature 180 are located in the isolation region having the dielectric layers 166 instead of gate electrode layers 172. As a result, the risk of electrical shorting between the gate electrode layer 172 and the conductive feature 180/conductive contact 178 is eliminated. Furthermore, the photo patterning window for forming the dielectric layers 169 is enlarged, because the dielectric layers 169 are not formed in the area of the conductive feature 180 and the conductive contact 178 to isolate them from the gate electrode layer 172. In addition, the CMP dishing effect is reduced during the formation of the dielectric layers 169.

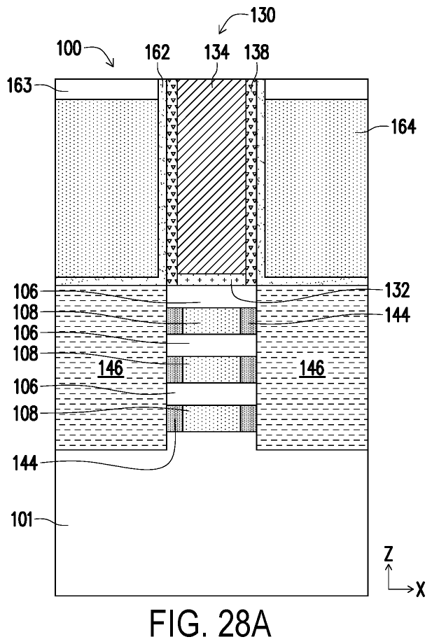

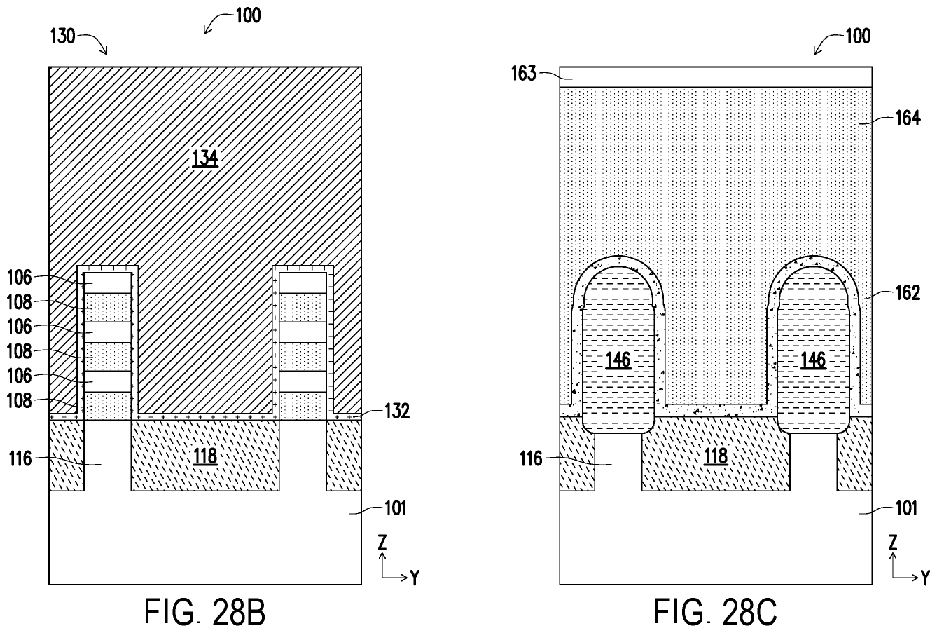

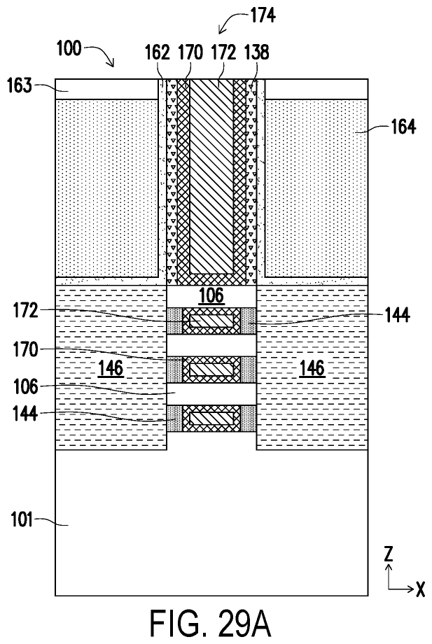

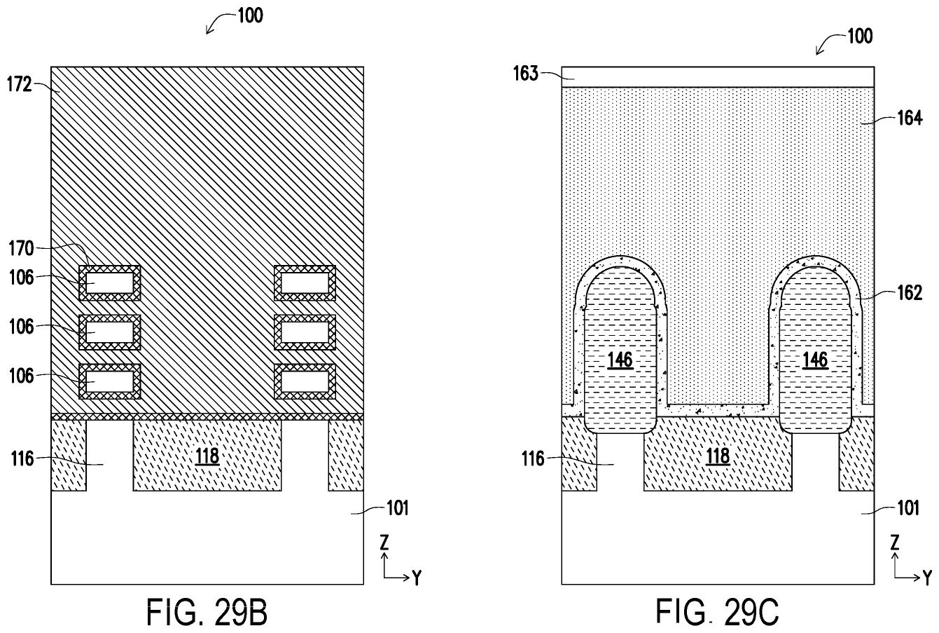

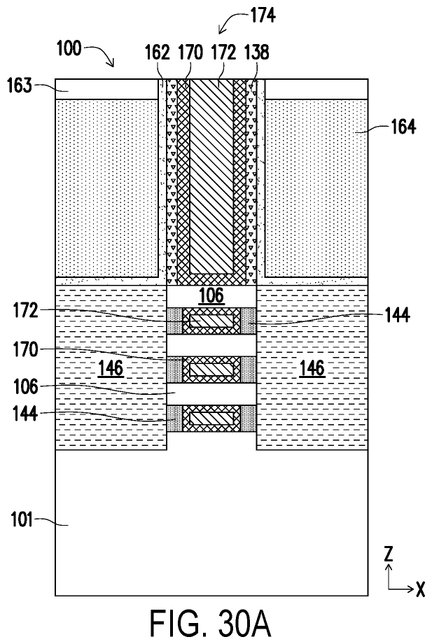

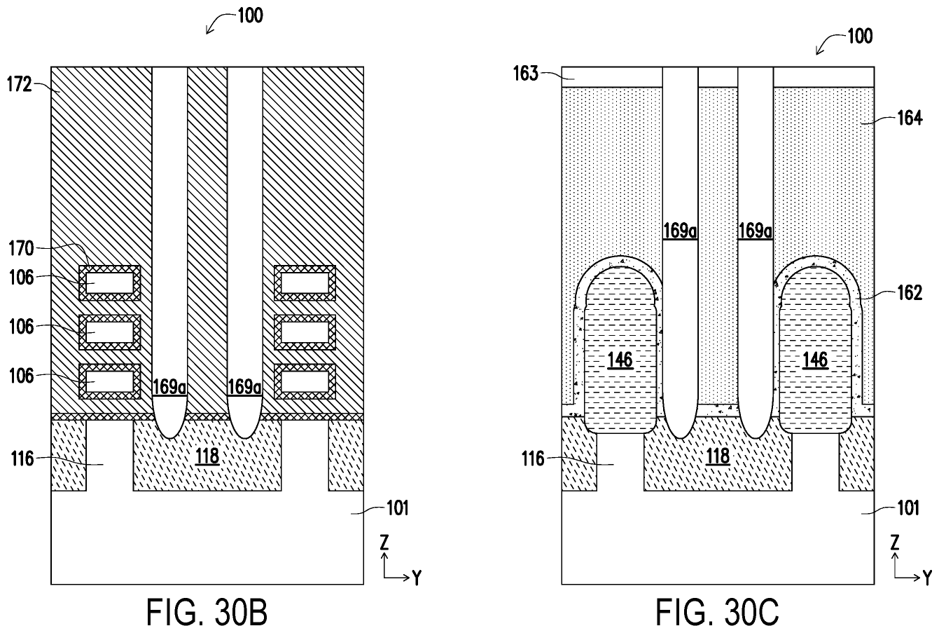

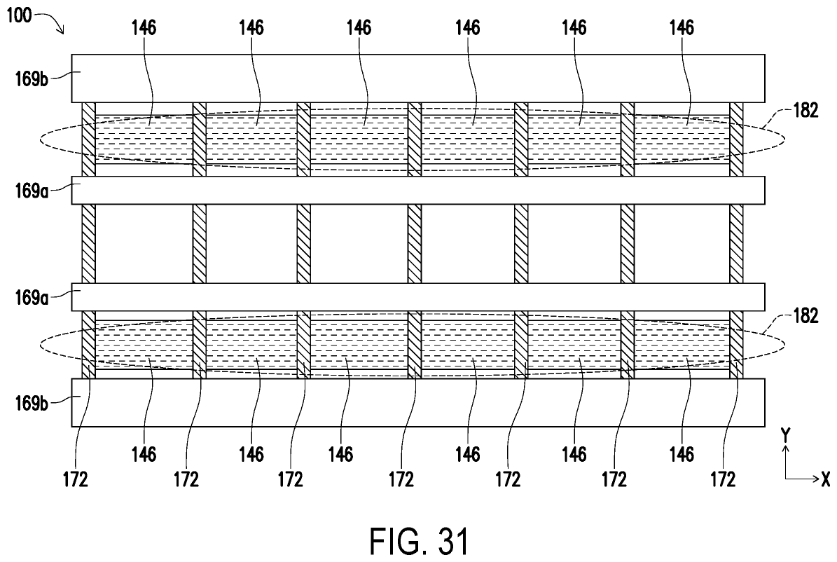

FIGS. 28A-30A are cross-sectional side views of various stages of manufacturing the semiconductor device structure 100 taken along line A-A of FIG. 6, in accordance with alternative embodiments. FIGS. 28B-30B are cross-sectional side views of various stages of manufacturing the semiconductor device structure 100 taken along line B-B of FIG. 6, in accordance with some embodiments. FIGS. 28C-30C are cross-sectional side views of various stages of manufacturing the semiconductor device structure 100 taken along line C-C of FIG. 6, in accordance with alternative embodiments. The semiconductor device structure 100 shown in FIGS. 28A, 28B, 28C is at the same manufacturing stage as the semiconductor device structure 100 shown in FIGS. 10A, 10B, 10C. Next, the sacrificial gate structures 130 are replaced with the gate structure 174, which includes the gate dielectric layers 170 and the gate electrode layers 172, as shown in FIGS. 29A, 29B, 29C. Next, the CMG process is performed to form the dielectric layers 169a, 169b (FIG. 31) in the gate electrode layer 172 and the gate dielectric layer 170, as shown in FIGS. 30B. The dielectric layers 169a also extend to the dielectric layer 163, the ILD layer 164, and the CESL 162 between the S/D regions 146, as shown in FIG. 30C.

FIG. 31 is a top view of the semiconductor device structure 100 shown in FIGS. 30A, 30B, and 30C, in accordance with some embodiments. Some components of the semiconductor device structure 100, such as the dielectric layer 163 and the CESL 162, are omitted in FIG. 31 for clarity. As shown in FIG. 31, the dielectric layers 169a, 169b are formed to separate the gate electrode layers 172 into multiple segments. An active region 182 is defined between the adjacent dielectric layers 169a, 169b. Each active region 182 may include a plurality of transistors, and each transistor may include the S/D regions 146 and a segment of the gate electrode layer 172. The segments of the gate electrode layers 172 located between the dielectric layers 169a are electrically isolated from the active regions 182 by the dielectric layers 169a.

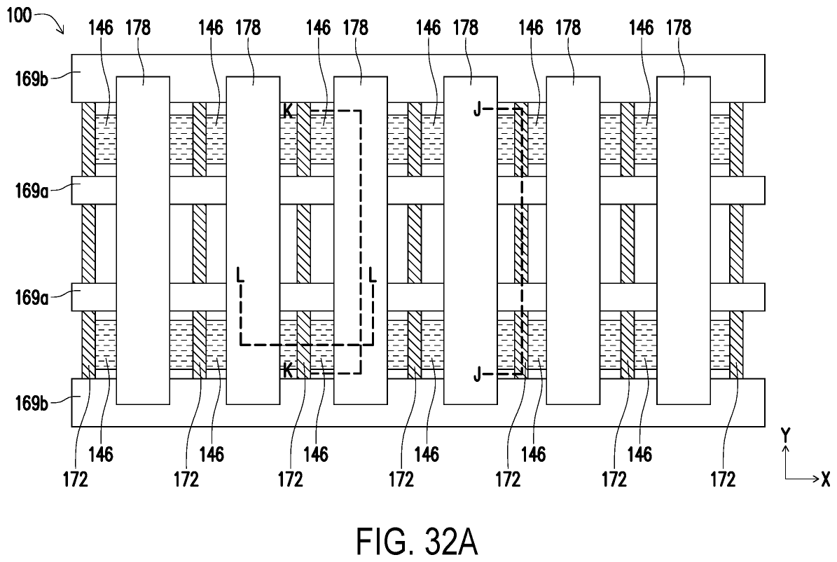

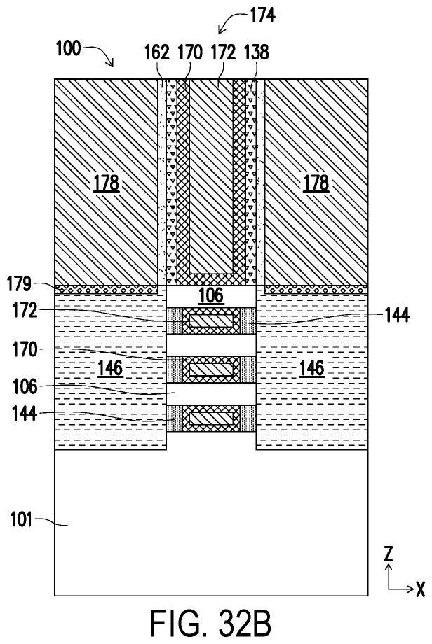

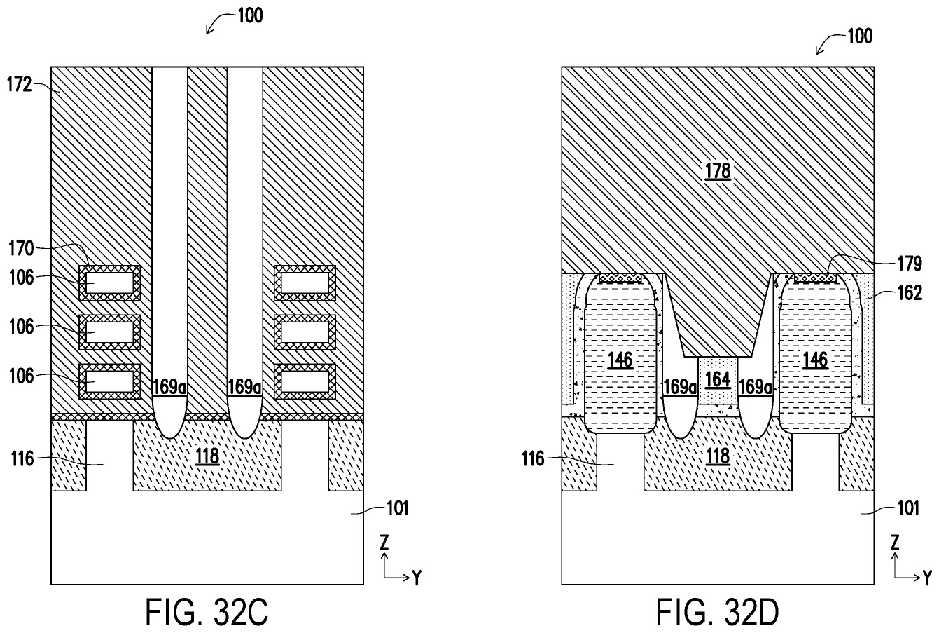

FIGS. 32A, 32B, 32C, 32D are various views of one of various stages of manufacturing the semiconductor device structure 100, in accordance with alternative embodiments. FIG. 32A is a top view of the semiconductor device structure 100, FIGS. 32B, 32C, 32D are cross-sectional side views of the semiconductor device structure 100 taken along lines L-L, J-J, K—K of FIG. 32A, respectively. As shown in FIGS. 32A, 32B, 32C, 32D, the conductive contacts 178 and the silicide layers 179 are formed. In some embodiments, as shown in FIG. 32A, a plurality of conductive contacts 178 extend along the Y-direction and traverse with respect to the fin structures 112 (or the S/D regions 146 and the first semiconductor layers 106). In some embodiments, the conductive contacts 178 can be continuous (connecting two or more S/D regions 146), as shown in FIGS. 32A and 32D. Furthermore, portions of the dielectric layers 169a located between adjacent gate electrode layers 172 may be removed, and the conductive contact 178 may extend to a level between two S/D regions 146, as shown in FIG. 32D.

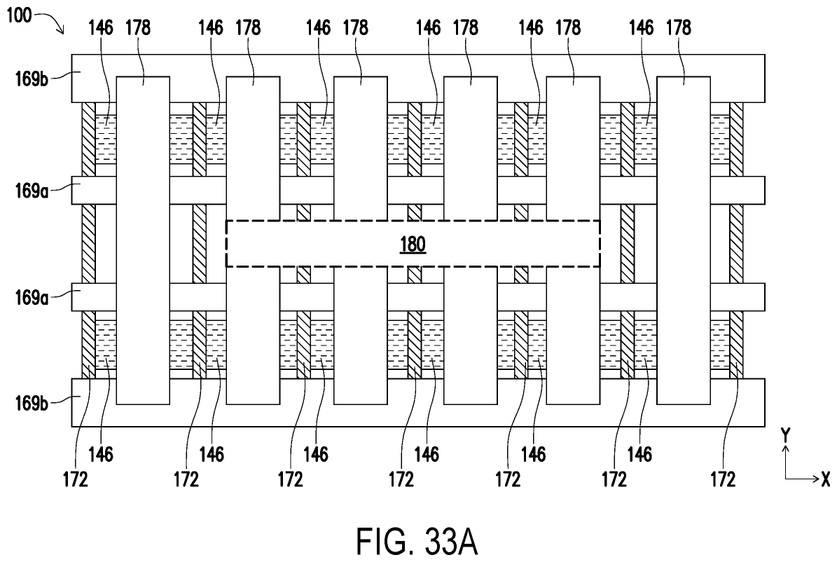

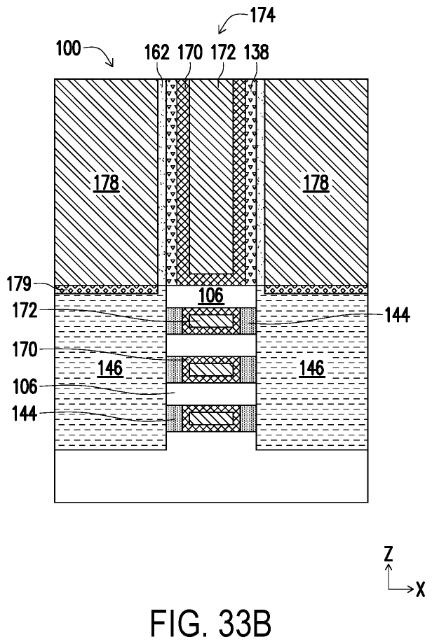

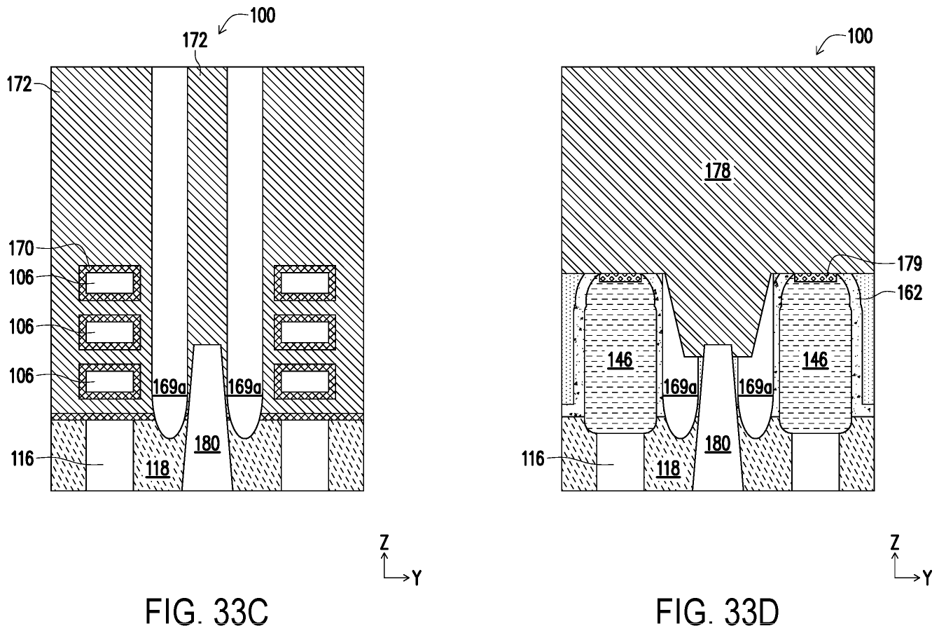

FIGS. 33A, 33B, 33C, 33D are various views of one of various stages of manufacturing the semiconductor device structure, in accordance with alternative embodiments. FIG. 33A is a top view of the semiconductor device structure 100, FIGS. 33B, 33C, 33D are cross-sectional side views of the semiconductor device structure 100 taken along lines L-L, J-J, K—K of FIG. 32A, respectively. After the formation of the conductive contacts 178, the interconnect structure (not shown) may be formed on the semiconductor device structure 100. The semiconductor device structure 100 is then flipped over for backside processing. Processes described in FIGS. 24A-C, 25A-C, and 26A-C may be performed on the semiconductor device structure 100 to form the conductive feature 180. As shown in FIGS. 33A, 33B, 33C, 33D, the conductive feature 180 is formed between the dielectric layers 169a. The conductive feature 180 may be electrically connected to a conductive feature, such as a conductive line, located in an interconnect structure (not shown) on the backside of the semiconductor device structure 100. Power may be supplied to the conductive contacts 178 from the backside via the conductive feature 180. Because the segments of the gate electrode layers 172 located in the active regions 182 (FIG. 31) are electrically isolated from the conductive feature 180, as shown in FIGS. 33A and 33C, the risk of electrical shorting between the conductive feature 180 and the gate electrode layer 172 is eliminated. Furthermore, the photo patterning window for forming the dielectric layers 169a, 169b is enlarged, because the dielectric layers 169a, 169b are not formed to surround the conductive feature 180 to isolate it from the gate electrode layer 172. In addition, the CMP dishing effect is reduced during the formation of the dielectric layers 169a, 169b.

Embodiments of the present disclosure provide a semiconductor device structure and methods of forming the same. In some embodiments, the semiconductor device structure includes a conductive feature 180 disposed in a dielectric layer 166. The dielectric layer 166 has a first end and a second end opposite the first end. A first S/D region 146 is located on a first side of the first end of the dielectric layer 166, a second S/D region 146 is located on a second side opposite the first side of the first end of the dielectric layer 166, a third S/D region 146 is located on a third side of the second end of the dielectric layer 166, and a fourth S/D region 146 is located on a fourth side opposite the third side of the second end of the dielectric layer 166. The conductive feature 180 is electrically connected to a conductive contact 178, which is electrically connected to active S/D regions 146. Some embodiments may achieve advantages. For example, by forming the conductive feature 180 in the dielectric layer 166, the risk of electrical shorting between the conductive feature 180 and the gate electrode layer 172 is eliminated.

An embodiment is a semiconductor device structure. The structure includes a first source/drain region, a second source/drain region disposed adjacent the first source/drain region along a first direction, and a third source drain region. The first source/drain region and the third source/drain region are aligned along a second direction substantially perpendicular to the first direction. The structure further includes a fourth source/drain region disposed adjacent the third source/drain region along the first direction and a first dielectric layer having a first end and a second end opposite the first end. The first and second source/drain regions are disposed on opposite sides of the first end of the first dielectric layer, and the third and fourth source/drain regions are disposed on opposite sides of the second end of the first dielectric layer. The structure further includes a conductive contact disposed between the first and third source/drain regions and between the second and fourth source/drain regions, and the conductive contact is disposed in the first dielectric layer. The structure further includes a conductive feature disposed in the first dielectric layer, and the conductive feature is electrically connected to the conductive contact.

Another embodiment is a semiconductor device structure. The structure includes a first gate electrode layer, a first dielectric layer disposed in the first gate electrode layer, a second dielectric layer disposed in the first gate electrode layer, a conductive feature disposed in the first gate electrode layer between the first and second dielectric layers, a first conductive contact disposed over and in contact with the conductive feature, and a second conductive contact disposed over and in contact with the conductive feature. The gate electrode layer is disposed between the first and second conductive contacts.

A further embodiment is a method for forming a semiconductor device structure. The method includes forming a first sacrificial gate electrode layer and a second sacrificial gate electrode layer, replacing a portion of the first sacrificial gate electrode layer with a first dielectric layer and a portion of the second sacrificial gate electrode layer with a second dielectric layer, and forming first, second, third, fourth source/drain regions. The first and second source/drain regions are formed on opposite sides of a first end of the first dielectric layer, and the third and fourth source/drain regions are formed on opposite sides of a second end of the first dielectric layer. The method further includes forming an interlayer dielectric layer over the first, second, third, and fourth source/drain regions, forming a conductive contact in the first and second dielectric layers and in the interlayer dielectric layer, flipping over the semiconductor device structure, and forming a conductive feature in the first and second dielectric layers. The conductive feature is electrically connected to the conductive contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a first source/drain region;
a second source/drain region disposed adjacent the first source/drain region along a first direction;
a third source/drain region, wherein the first source/drain region and the third source/drain region are aligned along a second direction substantially perpendicular to the first direction;
a fourth source/drain region disposed adjacent the third source/drain region along the first direction;
a first dielectric layer having a first end and a second end opposite the first end, wherein the first and second source/drain regions are disposed on opposite sides of the first end of the first dielectric layer, and the third and fourth source/drain regions are disposed on opposite sides of the second end of the first dielectric layer;
a conductive contact disposed between the first and third source/drain regions and between the second and fourth source/drain regions, wherein the conductive contact is disposed in the first dielectric layer; and
a conductive feature disposed in the first dielectric layer, wherein the conductive feature is electrically connected to the conductive contact.

2. The semiconductor device structure of claim 1, further comprising a second dielectric layer disposed adjacent the first dielectric layer, wherein the conductive contact and the conductive feature are disposed in the second dielectric layer.

3. The semiconductor device structure of claim 2, wherein the second dielectric layer has a third end and a fourth end opposite the third end, the first source/drain region is disposed adjacent the third end of the second dielectric layer, and the third source/drain region is disposed adjacent the fourth end of the second dielectric layer.

4. The semiconductor device structure of claim 2, further comprising a third dielectric layer disposed adjacent the first dielectric layer, wherein the conductive contact and the conductive feature are disposed in the third dielectric layer.

5. The semiconductor device structure of claim 4, wherein the first, second, and third dielectric layers are substantially parallel to each other.

6. The semiconductor device structure of claim 1, wherein the conductive feature is disposed between the first and third source/drain regions and between the second and fourth source/drain regions.

7. A semiconductor device structure, comprising:
a first gate electrode layer;
a first dielectric layer disposed in the first gate electrode layer;
a second dielectric layer disposed in the first gate electrode layer;
a conductive feature disposed in the first gate electrode layer between the first and second dielectric layers;
a first conductive contact disposed over and in contact with the conductive feature; and
a second conductive contact disposed over and in contact with the conductive feature, wherein the gate electrode layer is disposed between the first and second conductive contacts.

8. The semiconductor device structure of claim 7, further comprising a second gate electrode layer disposed adjacent the first conductive contact, wherein the first and second dielectric layers are disposed in the second gate electrode layer.

9. The semiconductor device structure of claim 8, wherein the conductive feature is disposed in the second gate electrode layer.

10. The semiconductor device structure of claim 7, further comprising a first source/drain region disposed on a first side of a first end of the first gate electrode layer, a second source/drain region disposed on a second side opposite the first side of the first end of the first gate electrode layer, a third source/drain region disposed on a third side of a second end opposite the first end of the first gate electrode layer, and a fourth source/drain region disposed on a fourth side opposite the third side of the second end of the first gate electrode layer.

11. The semiconductor device structure of claim 10, wherein the first conductive contact is electrically connected to the first and third source/drain regions, and the second conductive contact is electrically connected to the second and fourth source/drain regions.

12. The semiconductor device structure of claim 11, further comprising a first silicide layer disposed between the first conductive contact and the first source/drain region, a second silicide layer disposed between the first conductive contact and the third source/drain region, a third silicide layer disposed between the second conductive contact and the second source/drain region, and a fourth silicide layer disposed between the second conductive contact and the fourth source/drain region.

13. The semiconductor device structure of claim 12, further comprising a first plurality of semiconductor layers surrounded by the first gate electrode layer and a second plurality of semiconductor layers surrounded by the first gate electrode layer, wherein the first and second dielectric layers are disposed between the first and second pluralities of semiconductor layers.

14. A method for forming a semiconductor device structure, comprising:
forming a first sacrificial gate electrode layer and a second sacrificial gate electrode layer;
replacing a portion of the first sacrificial gate electrode layer with a first dielectric layer and a portion of the second sacrificial gate electrode layer with a second dielectric layer;
forming first, second, third, fourth source/drain regions, wherein the first and second source/drain regions are formed on opposite sides of a first end of the first dielectric layer, and the third and fourth source/drain regions are formed on opposite sides of a second end of the first dielectric layer;
forming an interlayer dielectric layer over the first, second, third, and fourth source/drain regions;
forming a conductive contact in the first and second dielectric layers and in the interlayer dielectric layer;
flipping over the semiconductor device structure; and
forming a conductive feature in the first and second dielectric layers, wherein the conductive feature is electrically connected to the conductive contact.

15. The method of claim 14, wherein the first and second dielectric layers are formed over an insulating material, and the conductive feature is formed in the insulating material.

16. The method of claim 15, further comprising forming first and second pluralities of semiconductor layers, wherein the first and second sacrificial gate electrode layers are formed over the first and second pluralities of semiconductor layers.

17. The method of claim 16, further comprising removing portions of the first and second pluralities of semiconductor layers after removing the portions of the first and second sacrificial gate electrode layers.

18. The method of claim 17, further comprising removing portions of a substrate located below the portions of the first and second pluralities of semiconductor layers.

19. The method of claim 18, wherein the first and second dielectric layers extend into the substrate.

20. The method of claim 19, further comprising thinning down the substrate to expose the insulating material and the first and second dielectric layers.
